(19) United States
(12) Patent Application Publication
(10) Pub. No.: US 2025/0273468 A1
(43) Pub. Date: Aug. 28, 2025

(54) METHOD FOR FORMING TITANIUM FILM, AND DEVICE FOR FORMING TITANIUM FILM

(71) Applicant: TOKYO ELECTRON LIMITED, Tokyo (JP)

(72) Inventors: Tatsuya SANO, Yamanashi (JP); Satoshi YOSHIDA, Yamanashi (JP); Yuya SAKAMOTO, Yamanashi (JP)

(21) Appl. No.: 18/696,721

(22) PCT Filed: Sep. 21, 2022
(86) PCT No.: PCT/JP2022/035223

§ 371 Date: Sep. 6, 2024

(30) Foreign Application Priority Data
Oct. 5, 2021 (JP) 2021-164248

(51) Int. Cl. H01L 21/285; C23C 16/14; C23C 16/455; C23C 16/46; C23C 16/505; C23C 16/52; H01J 37/32

(52) U.S. Cl. CPC H01L 21/28568; C23C 16/14; C23C 16/45542; C23C 16/45544; C23C 16/45553; C23C 16/46; C23C 16/505; C23C 16/52; H01J 37/32146; H01J 37/32724; H01J 2237/332

(57) ABSTRACT

There is provided a method of forming a titanium film in a recess formed on a surface of a substrate. The method comprises: supplying a titanium precursor gas to the substrate on which the recess is formed with an aspect ratio of 25 or more, which is a ratio of a depth dimension to a width dimension; and forming the titanium film in the recess by alternately repeating, multiple times, application of radio frequency power to a space to which the precursor gas is supplied while alternatively repeating turning on/off of the radio frequency power to convert the titanium precursor gas into plasma, and subsequent suspension of the application of the radio frequency power for a period longer than one cycle of on/off of the radio frequency power, during a period of supplying the titanium precursor gas.

### TECHNICAL FIELD

The present disclosure relates to a method for forming a titanium film and a device for forming a titanium film.

### BACKGROUND

In a process of manufacturing power devices or devices for integrated circuits, there is a case where a metal film, for example, a titanium film, is formed in a recess such as a trench and a via hole formed on a surface of a semiconductor wafer (hereinafter referred to as a “wafer”) which is a substrate.

On the other hand, the aspect ratio, which is the ratio of the width dimension to the depth dimension of a recess, tends to increase as performance, functionality, and integration of such devices increase.

For example, Patent Document 1 discloses a technique for forming a Ti film in a contact hole formed in a Si substrate by introducing TiCl₄ gas into a chamber in which the Si substrate is placed and then generating plasma in the chamber. This Ti film becomes a TiSi film by reacting with the underlying Si. In addition, Patent Document 2 discloses a technique for forming a titanium silicide film by alternately repeating supply of titanium compound gas to a Si wafer on which contact holes are formed and subsequent plasma supply of hydrogen gas to react with silicon on the surface of the Si wafer.

### PRIOR ART DOCUMENTS

### Patent Documents

Patent Document 1: Japanese Laid-open Patent Publication No. 2010-111888
Patent Document 2: Japanese Laid-open Patent Publication No. 2008-112803

### SUMMARY

### Problems to Be Resolved by the Invention

The present disclosure provides a technique for forming a titanium film within a recess that is formed in a substrate and has an aspect ratio of 25 or more.

### Means for Solving the Problems

The present disclosure relates to a method for forming a titanium film in a recess formed on a surface of a substrate, the method including supplying a titanium precursor gas to the substrate on which the recess is formed with an aspect ratio of 25 or more, which is a ratio of a depth dimension to a width dimension, and forming the titanium film in the recess by alternately repeating, multiple times, application of radio frequency power to a space to which the precursor gas is supplied while alternatively repeating turning on/off of the radio frequency power to convert the titanium precursor gas into plasma and subsequent suspension of the application of the radio frequency power for a period longer than one cycle of on/off of the radio frequency power, during a period in which the supplying of the titanium precursor gas is performed.

### Effect of the Invention

According to the present disclosure, a titanium film can be formed in a recess formed on a substrate where an aspect ratio of the recess is 25 or more.

### BRIEF DESCRIPTION OF THE DRAWINGS

FIG. 1 is a schematic diagram showing formation of a Ti film according to a comparative embodiment.

FIG. 2 is a schematic diagram showing formation of a Ti film according to the present disclosure.

FIG. 3 is a longitudinal side view showing a configuration example of a Ti film formation device.

FIG. 4 is a time chart according to application of radio frequency power during the forming a Ti film.

FIG. 5 is a schematic diagram showing formation of a Ti film according to another embodiment.

FIG. 6 is an electron micrograph showing results of an experiment on formation of a Ti film in a recess.

### DETAILED DESCRIPTION

### Ti Film Formation Method According to Comparative Embodiment

Before illustrating a method of forming a titanium (Ti) film according to the present disclosure, problems of a film formation method according to a comparative embodiment will be described.

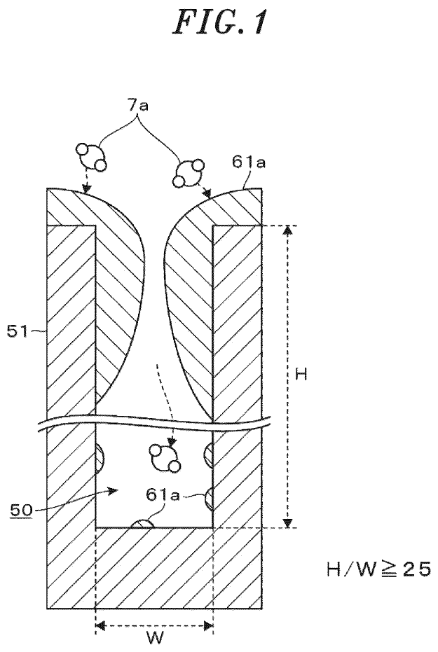

FIG. 1 shows a case in which a Ti film 61a is formed in a recess 50 formed on the surface of a wafer, for example, in the manufacture of a power device using the film formation method according to the comparative embodiment. In this example, the recess 50 is formed in a silicon member 51 constituting a wafer W. Accordingly, the silicon member 51 is exposed on the side walls and the bottom surface of the recess 50. In this example, the Ti film 61a is formed in the recess 50 having an aspect ratio of 25 or more, which is the ratio of the depth dimension H to the width dimension W. In the case of a power device, a case in which the width dimension W of the recess 50 is 0.4 μm in the range of 0.1 μm to 5 μm and the depth dimension H is 10 μm in the range of 2.5 μm to 125 μm may be illustrated. In addition, the range of the depth dimension written on the left is the minimum range in which the aspect ratio is 25 when the width dimension W is 0.1 μm to 5 μm, and the recess 50 deeper than this may be formed.

In the comparative embodiment, the Ti film 61a is formed using a known plasma chemical vapor deposition (CVD) method. In this method, titanium tetrachloride (TiCl₄) gas, which is a titanium precursor gas, and hydrogen (H₂) gas, which is a reaction gas (reduction gas), are continuously supplied to a processing space. Then, a radio frequency power of hundreds of kHz to several GHz, ranging from 800 W to 1300 W, for example, is applied to convert the gases into plasma. Here, the wafer W is heated at a temperature of approximately 450° C. to 650° C.

Through the above-described processing, highly reactive TiCl₂ radicals 7a are abundantly formed in the vicinity of the recess 50, and thus, the formation of the Ti film 61a progresses. Here, under an environment in which the formation of the Ti film 61a by the highly reactive TiCl₂ radicals 7a is dominant, reaction proceeds rapidly and Ti may be deposited before the TiCl₂ radicals 7a enter the lower region in the recess 50. As a result, as shown in FIG. 1, the Ti film 61a is formed near the opening of the recess 50, and the TiCl₂ radicals 7a are prevented from entering the recess 50, and thus, there is a high risk that formation of the Ti film 61 with a uniform film thickness will become difficult.

This tendency becomes more likely to occur as the aspect ratio of the recess 50 increases, and it is very difficult to form the Ti film 61 with a uniform film thickness in the recess 50 which has an aspect ratio of 25 or more, in other words, which can also be called a “super deep hole”. Additionally, when the width dimension W is 0.4 μm, the depth dimension H of the recess 50, generally called a “deep hole”, is at most about 5 μm (aspect ratio is 12.5).

### Film Formation Device

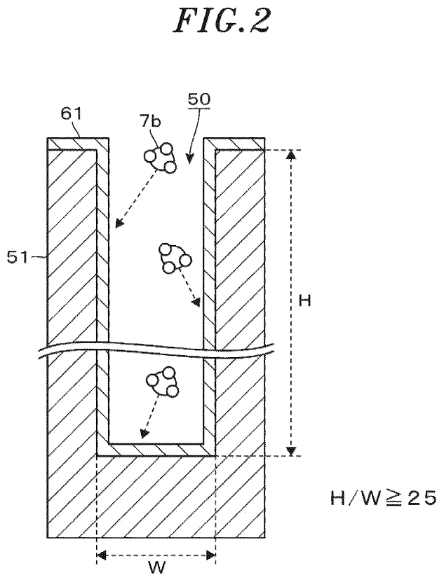

In the film formation method according to the present disclosure, by devising supply of radio frequency power, TiCl₃ radicals 7b, which are less reactive than TiCl₂ radicals 7a, are introduced into the recess 50 while film formation using the TiCl radicals 7b is carried out (FIG. 2). Accordingly, formation of the Ti film 61 with a uniform film thickness in the recess 50 with a high aspect ratio is achieved. In addition, the configuration of the silicon member 51 or the recess 50 in FIG. 2 is the same as the example described using FIG. 1.

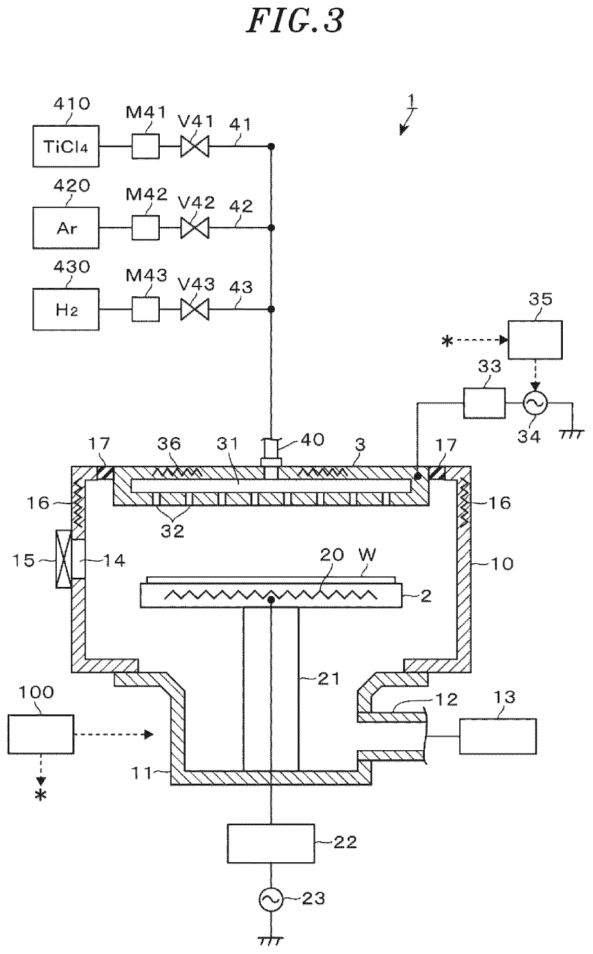

Hereinafter, a configuration example of the film formation device 1 for performing the film formation method will be described with reference to FIG. 3.

FIG. 1 is a longitudinal side view of the film formation device 1 of this example. This film formation device 1 is configured as a device that continuously supplies TiCl₄ gas, H₂ gas, and argon (Ar) gas to the surface of the wafer W and forms a Ti film 61 using a plasma (CVD) method.

The film formation device 1 includes a grounded metal processing chamber 10 having corrosion resistance against chlorine and having a substantially cylindrical shape. An exhaust chamber 11 having a cylindrical shape, for example, which protrudes downward is formed in the center of the bottom surface of the processing chamber 10, and an exhaust passage 12 is connected to the side of the exhaust chamber 11.

A vacuum exhaust part 13 including a pressure regulating valve configured as, for example, a butterfly valve is connected to the exhaust passage 12 and is configured to reduce the pressure inside the processing chamber 10 to a preset vacuum pressure. The wafer W is processed in the space within the processing chamber 10.

A loading/unloading port 14 for loading and unloading the wafer W is formed between the processing chamber 10 and a vacuum transfer chamber (not shown) on the side of the processing chamber 10. The loading/unloading port 14 is configured to be able to be opened and closed by means of a gate valve 15. Additionally, a heater 16 for controlling the temperature in the processing chamber 10 is embedded in the wall portion constituting the processing chamber 10.

Additionally, a mounting table 2 is provided in the processing chamber 10 to maintain the wafer W approximately horizontally. The mounting table 2 is supported by a support 21 extending from the bottom of the exhaust chamber 11. A heater 20, which is a heating part, is embedded in the mounting table 2 and can heat the wafer W at a set temperature. In this example, the heating temperature of the wafer W is set to 500° C. in the range of 400° C. to 800° C., for example.

Additionally, a radio frequency power source 23 that supplies radio frequency power for attracting ions is connected to the mounting table 2 via a matching device 22. Further, the mounting table 2 is provided with a lifting pin(s) (not shown) for holding and moving up and down the wafer W on the mounting table 2. The wafer W can be exchanged between the mounting table 2 and an external transport mechanism (that is not shown) by moving the lifting pin up and down.

Additionally, a flat disk-shaped shower head 3 is provided on the ceiling of the processing chamber 10 to supply a substrate processing gas toward the wafer W. The shower head 3 is mounted on the processing chamber 10 via an insulating member 17.

A diffusion chamber 31 is formed inside the shower head 3 to diffuse gas. Additionally, a plurality of discharge holes 32 are provided in a distributed manner on the bottom surface of the shower head 3 to discharge a gas toward the wafer W. Further, a heater 36 is embedded in the surface side of the shower head 3.

A radio frequency power source 34 that supplies radio frequency power for plasma formation is connected to the above-described shower head 3 via a matching device 33. That is, the film formation device 1 of the present disclosure constitutes a parallel plate-type plasma processing device with the shower head 3 forming an upper electrode and the mounting table 2 forming a lower electrode. When the wafer W is placed in the space between the shower head 3 and the mounting table 2, gases such as TiCl₄ gas and H₂ gas are supplied, and radio frequency power is applied, these gases ionize and plasma is formed.

The radio frequency power source 34 may be configured to supply radio frequency power at any of frequencies of 450 kHz, 13.56 MHz, 915 MHz, or 2.45 GHz. Additionally, the radio frequency power source 34 supplies radio frequency power within a range greater than 0 W and equal to or less than 2000 W.

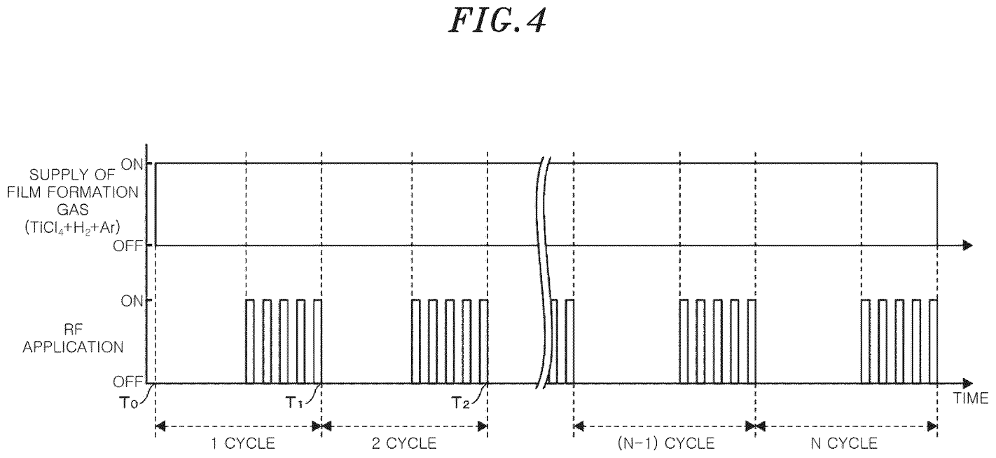

Further, the radio frequency power source 34 of this example is provided with a power feeding controller 35. The power feeding controller 35 has a function of controlling turning on/off switching of radio frequency power at a preset cycle and a function of performing control such that application of radio frequency power to the parallel plate and suspension of application of the radio frequency power are alternatively performed while performing the on/off switching. Details of this radio frequency power control will be described later with reference to FIG. 4. The radio frequency power source 34 and the power feeding controller 35 correspond to a radio frequency power supply of the present embodiment.

Additionally, the downstream end of a gas supply passage 40 is connected to the diffusion chamber 31 of the shower head 3. A TiCl₄ gas supply pipe 41, which is a flow path for supplying TiCl₄ gas serving as a titanium raw material/precursor gas, an Ar gas supply pipe 42, which is a flow path for supplying Ar gas added for plasma generation, and an H₂ gas supply pipe 43, which is a flow path for supplying H₂ gas serving as a reaction gas, join the upstream side of the gas supply passage 40.

A TiCl₄ gas supply source 410 is connected to the upstream end of the TiCl₄ gas supply pipe 41, and a flow rate regulator M41 and a valve V41 are provided in order from the upstream side (precursor gas supply). Additionally, an Ar gas supply source 420 is connected to the upstream end of the Ar gas supply pipe 42, and a flow rate regulator M42 and a valve V42 are provided in order from the upstream side. Additionally, an H₂ gas supply source 430 is connected to the upstream end of the H₂ gas supply pipe 43, and a flow rate regulator M43 and a valve V43 are provided in order from the upstream side (reaction gas supply).

This mixed gas of TiCl₄ gas, H₂ gas, and Ar gas (hereinafter also referred to as “film formation gas”) flows into the diffusion chamber 31 of the shower head 3 through the gas supply passage 40 and is supplied into the processing chamber 10 through the discharge holes 32.

The film formation device 1 having the above-described configuration includes a controller 100 as shown in FIG. 3. The controller 100 is composed of a computer including a storage in which a program is stored, a memory, and a CPU. The program includes instructions (steps) for outputting a control signal from the controller 100 to each part of the film formation device 1 and performing a process of forming the Ti film 61 by cutting off supply of each gas or supplying of radio frequency power. The program is stored in the storage of the computer, for example, a flexible disk, a compact disk, a hard disk, a magneto-optical (MO) disk, a non-volatile memory, or the like, read from this storage, and installed in the controller 100. FIG. 4 is an example of a time chart related to the film formation process performed using the above-described film formation device 1. This time chart schematically shows a timing of cutting off supply of film formation gas to the processing chamber 10 and a timing of applying radio frequency power (denoted as “RF” in FIG. 4) from the radio frequency power source 34.

According to this time chart, the film formation gas is continuously supplied at a preset flow rate for a predetermined period of time.

Meanwhile, the radio frequency power supplied through the shower head 3 (upper electrode) is applied to the space to which the film formation gas is supplied only at a predetermined timing during the supply period of the film formation gas.

Specifically, a time period in which the radio frequency power is applied to convert the film formation gas containing TiCl₄ gas into plasma and a time period in which application of the radio frequency power is stopped are set alternately. Further, during the time period in which the radio frequency power is applied, “on” (application of the radio frequency power) and “off” (suspension of application of the radio frequency power) of the radio frequency power are alternately repeated in a short period of time.

The on/off cycle of the high frequency may be a period in the range of 40 microseconds to 100 milliseconds, for example, 100 microseconds. The proportion of the period in which the radio frequency is on during this period may be 20% (on: 20 microseconds, off: 80 microseconds) in the range of 20.0% to 99.9%, for example.

Additionally, the period of the radio frequency power is 2.22 microseconds for 450 kHz, 73.7 nanoseconds for 13.56 MHz, 1.06 nanoseconds for 915 MHz, and 0.4 nanoseconds for 2.45 GHz. Therefore, during the “on” period, the radio frequency power is applied to the film formation gas for a period sufficiently longer than each period regardless of the frequency.

The period in which the radio frequency power is applied while repeating the above-described turning on/off and the period in which application of the radio frequency power is suspended are set within the range of 2 seconds or more and the range of 20 seconds or less, respectively. In this specification, the period in which the radio frequency power is applied may be set to 5 seconds, and the period in which application is suspended may be set to 5 seconds.

By setting the above-described periods, a plurality of on/off cycles are performed during the period in which the radio frequency power is applied. In addition, FIG. 4 schematically shows how radio frequency power is on/off, and does not show the actual number of times the radio frequency power is on/off. Additionally, for the period in which application of the radio frequency power is suspended, an application suspension time longer than one cycle of on/off of the radio frequency power is secured according to the above-described time setting. Accordingly, it is possible to clearly distinguish between the “off” time in the radio frequency power supply period, and the radio frequency power application suspension period.

For example, in a case where the Ti film 61 with a film thickness of 10 nm in the range of 0.1 nm to 150 nm is formed, application/suspension of application of the radio frequency power is performed for about 40 cycles in the range of 10 to 80 cycles.

In this specification, the reason for supplying the radio frequency power while repeating the on/off is to control ionization of the film formation gas during plasma generation. By not continuously applying the radio frequency power, formation of highly reactive TiCl₂ radicals 7a is suppressed and formation of more mildly reactive TiCl₃ radicals 7b is promoted.

In addition, the reason for providing the period in which application of the radio frequency power is suspended is to secure a period in which non-ionized film formation gas enters the recess 50.

Film formation gas supply cutoff control and radio frequency power application timing control are performed by the controller 100 or the power feeding controller 35, and the time chart shown in FIG. 4 is executed.

That is, the controller 100 controls opening and closing of the valves V41, V42, and V43, cuts off supply of each gas, and sets a flow rate of each of the flow rate regulators M41, M42, and M43. In addition, the controller 100 sets a radio frequency on/off cycle, a proportion of the period in which the radio frequency is on, a radio frequency power application period, and an application suspension period, for the power feeding controller 35.

### Film Formation Method

The operation of the film formation device 1 having the configuration described above will be described.

First, the gate valve 15 is opened, and the wafer W is loaded through the loading/unloading port 14 using a transfer mechanism provided in the vacuum transfer chamber that is not shown. The loaded wafer W is transferred from the transfer mechanism to the mounting table 2 via the lifting pin that is not shown and mounted on the upper surface of the mounting table 2. Next, when the transfer mechanism is retreated from the processing chamber 10 and the gate valve 15 is closed, the processing chamber 10 is evacuated by the vacuum exhaust part 13 to adjust the pressure in the processing chamber 10 to a preset pressure. Additionally, the wafer W is heated to 500° C. described above by the heater 20 (process of heating the substrate).

Thereafter, at a time T₀ shown in FIG. 4, supply of the film formation gas is started (process of supplying the titanium precursor gas). Then, after the elapse of a time (for example, 5 seconds) set as the period in which application of the radio frequency power is suspended, application of the radio frequency power is started at a time T₁. On/off is repeated during the period in which the radio frequency power is applied, as described above (for example, on; for 20 microseconds, off; for 80 microseconds), and the radio frequency power is applied for a preset time (e.g., 5 seconds). Application/suspension of application of the radio frequency power is repeated for a predetermined number of cycles (for example, 40 cycles). Here, it is desirable to supply relatively low power within the aforementioned power range (greater than 0 W and equal to or less than 2000 W) that can be supplied from the radio frequency power source 34. As an appropriate example, a case in which radio frequency power of 300 W within the range of 100 W to 500 W is applied can be exemplified.

According to the above-described operation, formation of the Ti film 61 is performed in an atmosphere in which mildly reactive TiCl₃ radicals 7b are formed in abundance, as schematically shown in FIG. 2. In addition, Ar gas included in the film formation gas does not inhibit the formation of plasma but has low reactivity with TiCl₄ gas unlike H₂ gas, and thus, it has a dilution effect of moderating the reactivity of the film formation gas.

Due to this effect, it can be ascertained that the progress of non-uniform film formation processing in which the Ti film 61a is formed near the opening of the recess 50 as in the comparative embodiment described using FIG. 1 can be suppressed.

Additionally, by providing the period in which application of the radio frequency power is suspended, a time for the film formation gas before plasma formation to enter the recess 50 is secured. Thereafter, plasma is formed between the parallel plates (the shower head 3 and the mounting table 2) including the inside of the recess 50 according to application of the radio frequency power. Due to this effect, it can be said that TiCl₃ radicals 7b are supplied to the side wall and the bottom surface located deep within the recess 50 and the Ti film 61 can also be formed in such regions.

In this manner, a preset number of cycles of application/suspension of application of the radio frequency power is performed to form the Ti film 61 with a preset film thickness (process of forming the Ti film 61). Next, application of the radio frequency power is terminated, and supply of the film formation gas and heating of the wafer W are stopped. Thereafter, the wafer W is unloaded from the processing chamber 10 in the reverse order to that of unloading processing, and loading of the next wafer W is awaited.

In this specification, in the Ti film 61 formed along the exposed surface of the silicon member 51, silicon atoms diffuse from the side of the silicon member 51 over time, and a titanium silicide (TiSi) film is immediately formed.

According to the embodiment described above, the following effects are obtained. A time for the film formation gas to enter the recess 50 is secured by providing the period in which application of the radio frequency power is suspended, and mildly reactive TiCl₃ radicals 7b are formed in abundance by repeatedly turning on/off the radio frequency power. Accordingly, the Ti film 61 with a uniform film thickness can be formed in the recess 50 formed on the wafer W with an aspect ratio of 25 or more.

### Other Embodiments

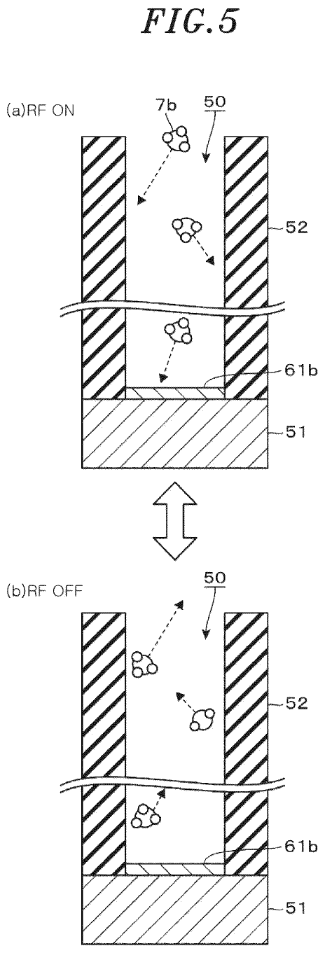

A target on which the Ti film 61 is formed using the film formation device 1 described in this specification using FIGS. 3 and 4 and the technique of applying radio frequency power is not limited to the configuration in which the recess 50 is formed in the silicon member 51 shown in FIG. 2. For example, as shown in (a) and (b) of FIG. 5, a configuration in which the recess 50 is formed in a silicon oxide film (SiO film 52) covering the silicon member 51 may be used. Additionally, in FIG. 5, components common to those shown in FIGS. 1 and 2 are denoted by the same symbols. In addition, although description is omitted in FIG. 5, the aspect ratio of the recess 50 shown in this figure is 25 or more.

In this specification, TiCl₄ gas also has the effect of etching titanium. On the one hand, compared to the silicon member 51, the SiO film 52 has a strong bond between silicon and oxygen and has a relatively weak bond with the Ti film 61 formed on the surface thereof. For this reason, the exposed surface of the SiO film 52 is easily etched with TiCl₄ gas as compared to the surface exposed by the silicon member 51 (the bottom surface of the recess 50 in the example shown in FIG. 5).

In the recess 50 where the SiO film 52 is exposed, film formation processing based on the time chart described using FIG. 4 is performed. Here, during the period in which the radio frequency power is turned on (indicated as “RF on” in (a) of FIG. 5), deposition of titanium occurs on the bottom surface of the recess 50 (where the silicon member 51 is exposed) and the side wall surface (where the SiO film 52 is exposed) due to TiCl₃ radicals 7b and the like.

On the other hand, during the period in which the radio frequency power is turned off (indicated as “RF off” in (b) of FIG. 5), TiCl₄ molecules react with deposited Ti on the side wall surface where bonding with Ti is weak. As a result, new TiCl_{X} is formed and etching of Ti deposited on the surface of the SiO film 52 is performed.

According to this effect, a Ti film 61b is barely formed on the side wall surface of the recess 50, whereas the Ti film 61b is formed only on the bottom surface of the recess 50 where the silicon member 51 is exposed.

In addition, a target device for forming the Ti film 61 using the film formation device 1 of the present disclosure and the radio frequency power application method is not limited to examples of power devices, and may be devices for integrated circuits. In this case, the technique of the present disclosure is also very suitable for forming the Ti film 61 in the recess 50 with an aspect ratio of 25 or more. In the case of a device for an integrated circuit in this specification, the width dimension W of the recess 50 may be within the range of 10.0 nm to 5.0 μm, and the depth dimension H may be within the range of 0.25 μm to 125 μm. In addition, the range of the depth dimension written on the left is the minimum range in which the aspect ratio is 25 when the width dimension W is 10.0 nm to 5.0 μm, and the recess 50 deeper than this may be formed. Additionally, the thickness of the TiN film 61 is within the range of, for example, 0.1 nm to 150 nm.

In addition, the recess 50 on which the Ti film 61 is formed using the method of the present disclosure is not limited to being formed to extend in the vertical direction intersecting the plate surface of the wafer W, as illustrated in FIG. 2, (a) of FIG. 5, and (b) of FIG. 5. For example, there are cases in which a longitudinal groove is formed on the surface of the wafer W and a plurality of transverse grooves is arranged in the thickness direction of the wafer W and formed on the side wall surface of the longitudinal groove. These transverse grooves may serve as recesses, and the Ti film 61 may be formed within the recesses.

Additionally, the member in which the recess 50 is formed is not limited to the silicon member 51, and may be made of another metal or metal compound.

In addition, the titanium precursor gas is not limited to the example of TiCl₄ gas, and may be another gas containing titanium atoms. As another gas, organic titanium, such as TDMAT (tetrakis dimethylamino titanium) or TDEAT (tetrakis diethylamino titanium), may be used. Additionally, supplying a reaction gas (H₂ gas in the above-described example) together with the titanium precursor gas is not an essential requirement. For example, a mixed gas of titanium precursor gas and Ar gas may be supplied into the processing chamber 10 as a film formation gas. In this case, the Ti film 61 can also be formed in the recess 50 by converting the film formation gas into plasma using radio frequency power applied using the above-described technique.

The embodiments disclosed here should be considered illustrative in all respects and not restrictive. The above-described embodiments may be omitted, replaced, or changed in various forms without departing from the appended claims and the general spirit thereof.

### Examples

### Experiment 1

The formation of the Ti film 61 was performed in accordance with the embodiment described using FIGS. 2 to 4, and the formation status of the Ti film 61 within the recess 50 was confirmed.

### A. Experimental Conditions

A plurality of circular hole-shaped recesses 50 each having a width (diameter) W of 0.2 μm and a depth H of 10 μm (aspect ratio of 50) is formed on the surface of a silicon wafer W. For this wafer W, the Ti film 61 is formed by applying radio frequency power using the film formation device 1 described with reference to FIG. 3 on the basis of the time chart described with reference to FIG. 4.

A supply flow rate of TiCl₄ gas is 18 sccm, a supply flow rate of Ar gas is 1600 sccm, a supply flow rate of H₂ gas is 4000 sccm, the pressure in the processing chamber 10 is set to 0.67 kPa (5 Torr), and a heating temperature of the wafer W is set at 500° C. Regarding the supply of radio frequency power, the on/off cycle of the radio frequency power is set to 100 microseconds (on: 20 microseconds, off: 80 microseconds), the period in which the radio frequency power is applied is set to 5 seconds, and the period in which application is suspended is set to 5 seconds. Application of the radio frequency power is turned on/off for 40 cycles to form the Ti film 61.

### B. Experimental Results

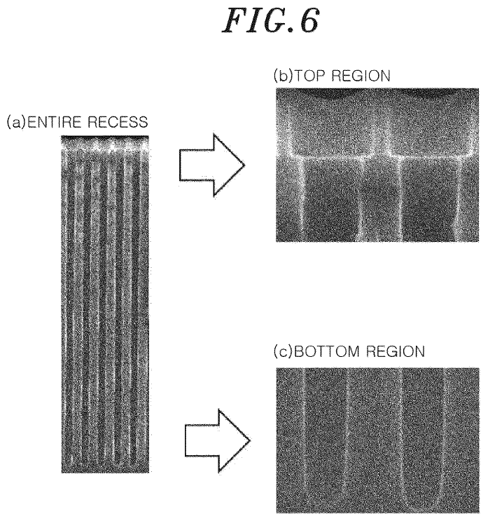

FIG. 6 shows an enlarged electron micrograph of the wafer W after the Ti film 61 has been deposited thereon, in which the area where the recesses 50 are formed, captured using a scanning electron microscope (SEM). (a) of FIG. 6 is a photograph of the entire recesses 50, and (b) and (c) of FIG. 6 are partial enlarged photographs of the top or bottom regions of the recesses 50. In (a) to (c) of FIG. 6, the white area formed along the side wall and bottom surface of the recesses 50 corresponds to the Ti film 61.

According to (a) to (c) of FIG. 6, the formation of the Ti film 61 near the opening of the recess 50 described using FIG. 1 was not observed. It can be confirmed that the Ti film 61 with a substantially uniform film thickness is formed from the top region to the bottom region of the recess 50. Therefore, the technique according to the present disclosure can be evaluated as a preferable method for forming a uniform Ti film 61 in the recess 50 with an aspect ratio of 25 or more.
W: Wafer
1: Film formation device
10: Processing chamber
2: Mounting plate
34: Radio frequency power source
410: TiCl₄ gas supply source
61: Ti film

1. A method of forming a titanium film in a recess formed on a surface of a substrate, the method comprising:
supplying a titanium precursor gas to the substrate on which the recess is formed with an aspect ratio of 25 or more, which is a ratio of a depth dimension to a width dimension; and
forming the titanium film in the recess by alternately repeating, multiple times, application of radio frequency power to a space to which the titanium precursor gas is supplied while alternatively repeating turning on/off of the radio frequency power to convert the titanium precursor gas into plasma, and subsequent suspension of the application of the radio frequency power for a period longer than one cycle of on/off of the radio frequency power, during a period of supplying the titanium precursor gas.

2. The method of claim 1, wherein the width dimension of the recess is in a range of 10 nm to 5 um.

3. The method of claim 1, wherein a film thickness of the titanium film is in a range of 0.1 nm to 150 nm.

4. The method of claim 1, wherein the cycle of on/off of the radio frequency power is a period in a range of 40 microseconds to 100 milliseconds.

5. The method of claim 1, wherein during the supplying of the titanium precursor gas, a reaction gas that reacts with the titanium precursor gas to form the titanium film is supplied in parallel.

6. The method of claim 5, wherein the titanium precursor gas is titanium tetrachloride gas, and the reaction gas is hydrogen gas.

7. The method of claim 1, wherein a period in which the radio frequency power is applied and a period in which the application of the radio frequency power is suspended are set within a range of 2 seconds or more and a range of 20 seconds or less, respectively.

8. The method of claim 1, further comprising:
heating the substrate at a temperature within a range of 400° C. to 800° C. during the period of supplying of the titanium precursor gas.

9. The method of claim 1, wherein the radio frequency power is greater than 0 W and equal to or less than 2000 W.

10. The method of claim 1, wherein the titanium film is formed along a surface where silicon is exposed, and after formation of the titanium film, the titanium film becomes a titanium silicide film due to diffusion of silicon atoms.

11. The method of claim 10, wherein the surface where silicon is exposed is a side wall surface and a bottom surface of the recess.

12. The method of claim 10, wherein the surface where the silicon is exposed is a bottom surface of the recess, silicon oxide is exposed on a side wall surface of the recess, and the titanium film is not formed on the side wall surface.

13. A device for forming a titanium film in a recess formed on a surface of a substrate, the device comprising:
a processing chamber that accommodates the substrate on which the recess is formed with an aspect ratio of 25 or more, which is a ratio of a depth dimension to a width dimension;
a precursor gas supply that supplies a titanium precursor gas to the processing chamber;
a radio frequency power supply that applies radio frequency power to a space within the processing chamber to which the titanium precursor gas is supplied from the precursor gas supply; and
a controller,
wherein the controller is configured to output a control signal for executing: supplying the titanium precursor gas to the substrate within the processing chamber; and forming the titanium film in the recess by alternately repeating, multiple times, application of radio frequency power to the space to which the titanium precursor gas is supplied while alternatively repeating turning on/off of the radio frequency power to convert the titanium precursor gas into plasma, and subsequent suspension of the application of the radio frequency power for a period longer than one cycle of on/off of the radio frequency power, during a period of supplying the titanium precursor gas.

14. The device of claim 13, wherein the controller outputs the control signal such that the cycle of on/off of the radio frequency power is a period in a range of 40 microseconds to 100 milliseconds.

15. The device of claim 13, further comprising:
a reaction gas supply that supplies a reaction gas, that reacts with the titanium precursor gas to form the titanium film, to the processing chamber;
wherein the controller outputs the control signal such that supply of the reaction gas is supplied in parallel during the supplying of the titanium precursor gas.

16. The device of claim 15, wherein the titanium precursor gas is titanium tetrachloride gas, and the reaction gas is hydrogen gas.

17. The device of claim 13, wherein the controller outputs the control signal such that a period in which the radio frequency power is applied and a period in which application of the radio frequency power is suspended are set within a range of 2 seconds or more and a range of 20 seconds or less, respectively.

18. The device of claim 13, further comprising:
a heater for heating the substrate accommodated in the processing chamber,
wherein the controller outputs a control signal for heating the substrate at a temperature in a range of 400° C. to 800° C. during the period of supplying of the titanium precursor gas.

19. The device of claim 13, wherein the controller outputs the control signal such that radio frequency power greater than 0 W and equal to or less than 2000 W is supplied.
